(19) United States
(12) Patent Application Publication
(10) Pub. No.: US 2022/0390680 A1
(43) Pub. Date: Dec. 8, 2022

(54) OPTICAL COMMUNICATION DEVICE

(71) Applicant: FUJIFILM Corporation, Tokyo (JP)

(72) Inventors: Yukito SAITOH, Minamiashigara-shi (JP); Katsumi SASATA, Minamiashigara-shi (JP); Hiroshi SATO, Minamiashigara-shi (JP)

(73) Assignee: FUJIFILM Corporation, Tokyo (JP)

(21) Appl. No.: 17/886,540

(22) Filed: Aug. 12, 2022

Related U.S. Application Data
(63) Continuation of application No. PCT/JP2021/004655, filed on Feb. 8, 2021.

(30) Foreign Application Priority Data
Feb. 14, 2020 (JP) 2020-023041
Apr. 14, 2020 (JP) 2020-072168
Aug. 13, 2020 (JP) 2020-136720

(51) Int. Cl. G02B 6/32; H04B 10/63; G02B 5/30; G02B 6/27; G02B 6/293; G02B 5/18; G02B 6/42

(52) U.S. Cl. CPC G02B 6/32; H04B 10/63; G02B 5/30; G02B 6/27; G02B 6/293; G02B 5/18; G02B 6/42

(57) ABSTRACT

Provided is an optical communication device, such as a wavelength locker, a wavelength demultiplexer, an optical coupling system, and an optical switching system, using a small-sized lens element. An optical communication device includes, as a lens element, a liquid crystal diffractive lens element having an optically anisotropic layer that is formed using a composition containing a liquid crystal compound, and has a liquid crystal alignment pattern in which an orientation of an optical axis of the liquid crystal compound changes while continuously rotating toward one direction, in a radial shape from an inside toward an outside, and in the liquid crystal alignment pattern, in a case where a length over which the orientation of the optical axis rotates by 180° in one direction in which the optical axis changes is a single period, a length of the single period gradually decreases from the inside toward the outside.

### CROSS-REFERENCE TO RELATED APPLICATIONS

This application is a Continuation of PCT International Application No. PCT/JP2021/004655 filed on Feb. 8, 2021, which claims priority under 35 U.S.C. § 119(a) to Japanese Patent Application No. 2020-023041 filed on Feb. 14, 2020, Japanese Patent Application No. 2020-072168 filed on Apr. 14, 2020 and Japanese Patent Application No. 2020-136720 filed on Aug. 13, 2020. Each of the above applications is hereby expressly incorporated by reference, in its entirety, into the present application.

### BACKGROUND OF THE INVENTION

### 1. Field of the Invention

The present invention relates to an optical communication device.

### 2. Description of the Related Art

With an increase in quantity of communication data every year, a communication device is required to have a higher capacity. For the higher capacity, wavelength division multiplex (WDM) is employed, and a dedicated light source unit (wavelength locker) plays a major role in realization of the wavelength division multiplex (for example, WO2016/201625A).

High performance of a coupler (for example, WO2016/206537A) that converts an optical fiber into an electrical signal, an optical multiplexer or a wavelength demultiplexer (for example, WO2018/010675A), and the like also contribute to realization of high-capacity communication.

### SUMMARY OF THE INVENTION

In WO2016/201625A, a light source, a collimating lens, an optical isolator, an etalon, and a condenser lens are mounted in the wavelength locker, and in particular, the collimating lens and the condenser lens are applied with an inorganic optical material, such as glass or quartz. For optical demands or restraictions in terms of processing or mounting, the lenses have a comparatively large size.

Similarly, the same collimating lens or collimating lens array may be used in the couple, the optical multiplexer, the wavelength demultiplexer, and the like, leading to a restriction to a size in terms of mounting. Not only simply a communication capacity per fiber but also an information processing capacity per space occupied by a reception and transmission processing device play an important role in the higher capacity of communication, and each device configuring the reception and transmission processing device or each member of the device is required to be further reduced in size.

Accordingly, an object of the present invention is to provide an optical communication device using a smaller-sized lens element.

Specifically, an object of the present invention is to provide an optical communication device including a wavelength locker using the lens element, an optical transmitter optical assembly using the wavelength locker, a wavelength demultiplexer, an optical displacer, an optical coupling system using the optical displacer, an optical switching system, and the like.

The inventors have found that the above-described object can be achieved with the following configuration.

[1] An optical communication device including;

a liquid crystal diffractive lens element having an optically anisotropic layer formed of a composition containing a liquid crystal compound, as a lens element,

in which the optically anisotropic layer of the liquid crystal diffractive lens element has a liquid crystal alignment pattern in which an orientation of an optical axis derived from the liquid crystal compound changes while continuously rotating toward one direction, in a radial shape from an inside toward an outside, and

in the liquid crystal alignment pattern, in a case where a length over which the orientation of the optical axis derived from the liquid crystal compound rotates by 180° in the one direction in which the orientation of the optical axis derived from the liquid crystal compound changes while continuously rotating is set as a single period, the length of the single period gradually decreases from the inside toward the outside.

[2] The optical communication device according to [1], further comprising a laser, and a wavelength locker unit,

in which the wavelength locker unit has a collimating lens, an optical isolator that regulates a traveling direction of light transmitted through the collimating lens, and an etalon that processes light transmitted through the optical isolator, and the collimating lens is the liquid crystal diffractive lens element, and

the optical communication device acts as a wavelength locker.

[3] The optical communication device according to [2],

in which the wavelength locker unit has a condenser lens downstream of the etalon in the traveling direction of the light.

[4] The optical communication device according to [2] or [3],

in which the collimating lens and the optical isolator are integrated.

[5] The optical communication device according to [1], further comprising

a base, and

a socket that is provided for connection of an optical fiber, a collimating lens through which light that is emitted from the optical fiber connected to the socket is transmitted, a demultiplexer block that is provided for wavelength separation of light transmitted through the collimating lens, and a condenser lens array having a plurality of condenser lenses that collect light of each wavelength range subjected to the wavelength separation by the demultiplexer block, the socket, the collimating lens, a demultiplexer block, and the condenser lens array being held on the base,

in which the condenser lenses of the condenser lens array are the liquid crystal diffractive lens element, and

the optical communication device acts as a wavelength demultiplexer.

[6] The optical communication device according to [5], further comprising

a folding prism that is held in the base downstream of the demultiplexer block in a traveling direction of light and folds the light of each wavelength range subjected to the wavelength separation by the demultiplexer block.

[7] The optical communication device according to [6],

in which, in a case where a surface on which the demultiplexer block is held is a front surface of the base, the condenser lens array is held on a back surface of the base, and

the light folded by the folding prism is transmitted through the base and is incident into the condenser lens array.

[8] The optical communication device according to [1], further comprising

an optical displacer that is provided for polarization separation,

in which the optical displacer has an incidence-side lens element, and a birefringent plate that is provided for the polarization separation of light transmitted through the incidence-side lens element, and

the incidence-side lens element is the liquid crystal diffractive lens element.

[9] The optical communication device according to [8], in which the optical displacer has an emission-side lens element that adjusts an optical path of light subjected to the polarization separation in the birefringent plate, downstream of the birefringent plate in a traveling direction of light.

[10] The optical communication device according to [8] or [9], further comprising

an optical fiber,

in which the incidence-side lens element transmits light emitted from the optical fiber.

[11] The optical communication device according to any one of [8] to [10], further comprising

a photonic device that includes a grating coupler, downstream of the optical displacer in a traveling direction of light,

in which the optical communication device functions as a polarization multiplex mode optical receiver.

[12] The optical communication device according to [1], further comprising

a collimating lens;

a spectral element that is provided for wavelength separation of light transmitted through the collimating lens; and

a spatial modulation element that modulates the light subjected to the wavelength separation by the spectral element,

in which the collimating lens is the liquid crystal diffractive lens element, and

the optical communication device acts as an optical switching system.

According to the present invention, it is possible to provide an optical communication device using a small-sized lens element.

According to the present invention, it is possible to provide an optical communication device having a wavelength locker, a wavelength demultiplexer, or the like using the lens element.

### BRIEF DESCRIPTION OF THE DRAWINGS

FIG. 1 is a diagram conceptually showing an example of a liquid crystal diffractive lens element that is used in an optical communication device of the present invention.

FIG. 2 is a diagram conceptually showing an example of a layer configuration of the liquid crystal diffractive lens element shown in FIG. 1.

FIG. 3 is a conceptual diagram illustrating a liquid crystal alignment pattern of another example of a liquid crystal diffractive lens element.

FIG. 4 is a conceptual diagram illustrating the action of the liquid crystal diffractive lens element shown in FIG. 3.

FIG. 5 is a conceptual diagram illustrating the action of the liquid crystal diffractive lens element shown in FIG. 3.

FIG. 6 is a conceptual diagram of an example of an exposure device that exposes an alignment film.

FIG. 7 is a diagram conceptually showing an example of an optical transmitter optical assembly including a wavelength locker that configures the optical communication device of the present invention.

FIG. 8 is a diagram conceptually showing an example of a lens-optical isolator integrated element in which a lens element and an optical isolator are integrated.

FIG. 9 is a side view conceptually showing an example of a wavelength demultiplexer that configures the optical communication device of the present invention.

FIG. 10 is a diagram conceptually showing the front of the wavelength demultiplexer shown in FIG. 9.

FIG. 11 is a diagram conceptually showing another side surface of the wavelength demultiplexer shown in FIG. 9.

FIG. 12 is a diagram conceptually showing an example of an optical displacer that configures the optical communication device of the present invention, and an optical coupling system including the optical displacer.

FIG. 13 is a diagram conceptually showing an optical switching system that configures the optical communication device of the present invention, and an optical coupling system including the optical switching system.

### DESCRIPTION OF THE PREFERRED EMBODIMENTS

Hereinafter, the present invention will be described in detail.

The description of the constituent elements described below is provided based on a representative embodiment of the present invention, but the present invention is not limited to such an embodiment.

In the specification, a numerical range represented using “to” means a range including numerical values before and after “to” as a lower limit value and an upper limit value.

A communication device of the present invention includes, as a lens element, a liquid crystal diffractive lens element having an optically anisotropic layer that is formed of a composition containing a liquid crystal compound and has a liquid crystal alignment pattern in which an orientation of an optical axis derived from the liquid crystal compound changes while continuously rotating toward one direction, in a radial shape from an inside toward an outside.

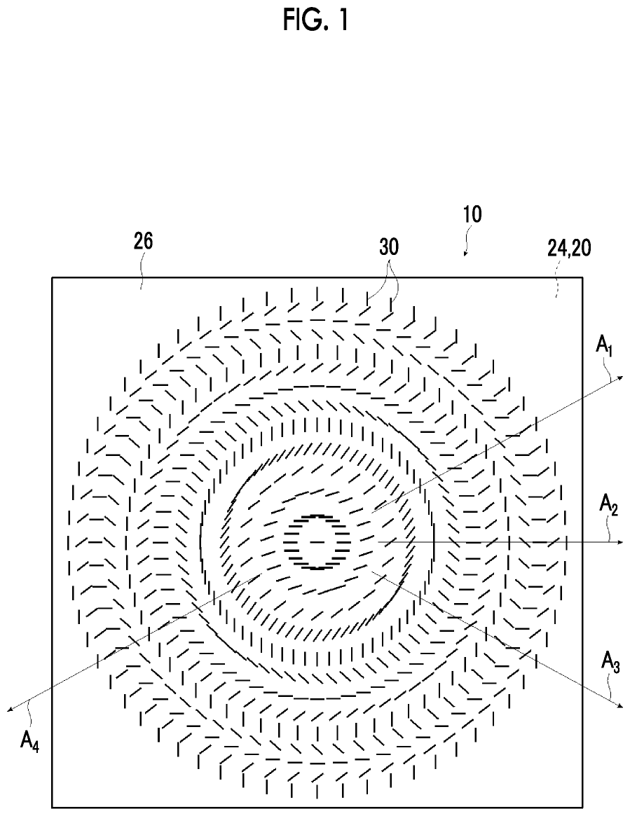

An example of a preferred optically anisotropic layer of such a liquid crystal diffractive lens element is an optically anisotropic layer that has a liquid crystal alignment pattern conceptually shown in a plan view of FIG. 1.

As described above, in the communication device of the present invention, a liquid crystal diffractive lens element 10 having an optically anisotropic layer 26 is used as a lens element. The optically anisotropic layer 26 of the liquid crystal diffractive lens element 10 has a liquid crystal alignment pattern in which an orientation of an optical axis derived from a liquid crystal compound changes while continuously rotating toward one direction, in a radial shape from an inside toward an outside. That is, the liquid crystal alignment pattern of the optically anisotropic layer 26 shown in FIG. 1 is a concentric circular pattern that has one direction in which an orientation of an optical axis derived from a liquid crystal compound 30 changes while continuously rotating, in a concentric circular shape from an inside toward an outside.

In FIGS. 1 to 4, since a rod-like liquid crystal compound is illustrated as the liquid crystal compound 30, the direction of the optical axis matches a longitudinal direction of the liquid crystal compound 30.

In the optically anisotropic layer 26, the orientation of the optical axis of the liquid crystal compound 30 changes along many directions from a center of the optically anisotropic layer 26 toward an outside, for example, a direction indicated by an arrow A₁, a direction indicated by an arrow A₂, a direction indicated by an arrow A₃, a direction indicated by an arrow A₄, . . . while continuously rotating.

Accordingly, in the optically anisotropic layer 26, a rotation direction of the optical axis of the liquid crystal compound 30 is the same direction in all directions (one direction). In the example shown in the drawing, the rotation direction of the optical axis of the liquid crystal compound 30 is counterclockwise in all directions of the direction indicated by the arrow A₁, the direction indicated by the arrow A₂, the direction indicated by the arrow A₃, and the direction indicated by the arrow A₄.

That is, in a case where the arrow A₁ and the arrow A₄ are regarded as one straight line, the rotation direction of the optical axis of the liquid crystal compound 30 is reversed at the center of the optically anisotropic layer 26 on the straight line. As an example, it is assumed that the straight line formed of the arrow A₁ and the arrow A₄ is toward a right direction (an arrow A1 direction) in the drawing. In this case, the optical axis of the liquid crystal compound 30 initially rotates clockwise from an outer direction toward the center of the optically anisotropic layer 26, the rotation direction is reversed at the center of the optically anisotropic layer 26, and thereafter, the optical axis of the liquid crystal compound 30 rotates counterclockwise from the center toward the outer direction of the optically anisotropic layer 26.

In the liquid crystal alignment pattern of optically anisotropic layer 26 of the liquid crystal diffractive lens element 10, in a case where a length over which the orientation of the optical axis derived from the liquid crystal compound rotates by 180° in one direction in which the orientation of the optical axis of the liquid crystal compound 30 changes while continuously rotating is a single period, a length of the single period gradually decreases from the inside toward the outside.

In circularly polarized light incident into the optically anisotropic layer 26 having the liquid crystal alignment pattern, an absolute phase changes depending on individual local regions having different orientations of the optical axes of the liquid crystal compound 30. In this case, an amount of change in absolute phase varies depending on the orientations of the optical axes of the liquid crystal compound 30 into which circularly polarized light is incident.

In the optically anisotropic layer (liquid crystal optical element) having the liquid crystal alignment pattern in which the orientation of the optical axis of the liquid crystal compound 30 changes while continuously rotating toward one direction, a refraction direction of transmitted light depends on a rotation direction of the optical axis of the liquid crystal compound 30. That is, in the liquid crystal alignment pattern, in a case where the rotation direction of the optical axis of the liquid crystal compound 30 is reversed, the refraction direction of transmitted light is reversed with respect to one direction in which the optical axis rotates.

A diffraction angle by the optically anisotropic layer 26 increases as the single period decreases. That is, diffraction of light by the optically anisotropic layer 26 increases as the single period decreases.

Accordingly, in the optically anisotropic layer 26 having the liquid crystal alignment pattern in a concentric circular shape, that is, the liquid crystal alignment pattern in which the optical axis changes while continuously rotating in a radial shape, transmission of a plurality of incident light (light beams) can be dispersed or converged depending on the rotation direction of the optical axis of the liquid crystal compound 30 and a turning direction of incident circularly polarized light. The liquid crystal diffractive lens element 10 collimates incident light, collection of incident light, and the like using the principle.

Hereinafter, the liquid crystal diffractive lens element 10 will be described in more detail.

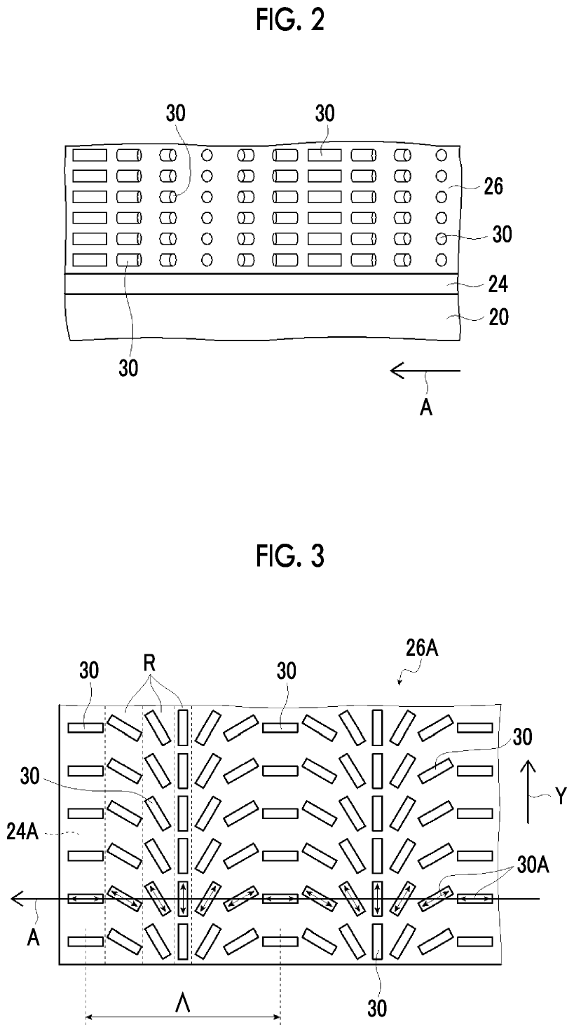

FIG. 2 conceptually shows a layer configuration of the liquid crystal diffractive lens element 10.

As an example, the liquid crystal diffractive lens element 10 shown in FIG. 2 has a support 20, an alignment film 24, and the above-described optically anisotropic layer 26.

In the communication device of the present invention, the layer configuration of the liquid crystal diffractive lens element is not limited thereto. That is, the liquid crystal diffractive lens element may be configured of the alignment film 24 and the optically anisotropic layer 26 while the support 20 is peeled off from the liquid crystal diffractive lens element 10 shown in FIG. 2. Alternatively, the liquid crystal diffractive lens element may be configured of only the optically anisotropic layer 26 while the support 20 and the alignment film 24 are peeled off from the liquid crystal diffractive lens element 10 shown in FIG. 2. Alternatively, the liquid crystal diffractive lens element may be configured by bonding a sheet-shaped material, such as a separate substrate, to the optically anisotropic layer 26.

That is, in the communication device of the present invention, various layer configurations can be used as long as the liquid crystal diffractive lens element has the optically anisotropic layer having the above-described liquid crystal alignment pattern in which the orientation of the optical axis derived from the liquid crystal compound changes while continuously rotating toward one direction, in a radial shape (concentric circular shape) from the inside toward the outside.

<<Support>>

In the liquid crystal diffractive lens element 10, the support 20 supports the alignment film 24 and the optically anisotropic layer 26.

As the support 20, various sheet-shaped materials (film or plate-shaped materials) can be used as long as the alignment film 24 and the optically anisotropic layer 26 can be supported.

The support 20 is preferably a transparent support, and examples of the support 20 include a polyacrylic resin film, such as polymethyl methacrylate, a cellulose resin film, such as cellulose triacetate, a cycloolefin polymer film (for example, product name “ARTON”, manufactured by JSR Corporation, and product name “ZEONOR”, manufactured by Zeon Corporation), polyethylene terephthalate (PET), polycarbonate, and polyvinyl chloride. The support is not limited to a flexible film, and may be a non-flexible substrate, such as a glass substrate.

A thickness of the support 20 is not limited, and may be appropriately set depending on the purpose of the liquid crystal diffractive lens element 10, the material for forming the support 20, and the like in a range where the alignment film and the optically anisotropic layer can be held.

The thickness of the support 20 is preferably 1 to 1000 μm, more preferably 3 to 250 μm, and still more preferably 5 to 150 μm.

<<Alignment Film>>

In the liquid crystal diffractive lens element 10, the alignment film 24 is formed on a surface of the support 20.

The alignment film 24 is an alignment film for aligning the liquid crystal compound 30 to a predetermined liquid crystal alignment pattern in a case of forming the optically anisotropic layer 26 of the liquid crystal diffractive lens element 10.

As described above, in the liquid crystal diffractive lens element 10 that is used as a lens element in the present invention, the optically anisotropic layer 26 has the liquid crystal alignment pattern in which the orientation of an optical axis 30A (see FIG. 3) derived from the liquid crystal compound 30 changes while continuously rotating along one in-plane direction (the above-described arrow A1 direction or the like), in a radial shape from the inside toward the outside. In other words, in the liquid crystal diffractive lens element 10 that is used as a lens element in the present invention, the liquid crystal alignment pattern of the optically anisotropic layer 26 is a concentric circular pattern that has one direction in which the orientation of the optical axis derived from the liquid crystal compound 30 changes while continuously rotating, in a concentric circular shape from the inside toward the outside.

In the present invention, in the liquid crystal alignment pattern of the optically anisotropic layer 26, in a case where the length over which the orientation of the optical axis 30A rotates by 180° in one direction in which the orientation of the optical axis 30A changes while continuously rotating is set as the single period (a rotation period of the optical axis), the length of the single period gradually decreases from the inside toward the outside. That is, in the liquid crystal alignment pattern of the optically anisotropic layer 26, the length of the single period gradually decreases from the center toward the outside.

Accordingly, the alignment film of the liquid crystal diffractive lens element 10 is formed such that the optically anisotropic layer 26 can form the liquid crystal alignment pattern.

In the following description, “the orientation of the optical axis 30A rotates” will also be simply referred to as “the optical axis 30A rotates”.

As the alignment film, various known alignment films can be used.

Examples of the alignment film include a rubbed film formed of an organic compound, such as a polymer, an obliquely deposited film formed of an inorganic compound, a film having a microgroove, and a film formed by lamination of Langmuir-Blodgett (LB) films formed with a Langmuir-Blodgett's method using an organic compound, such as ω-tricosanoic acid, dioctadecylmethylammonium chloride, or methyl stearate.

The alignment film formed by rubbing treatment can be formed by rubbing a surface of a polymer layer with paper or fabric in a given direction several times.

Preferable examples of a material used for the alignment film include polyimide, polyvinyl alcohol, a polymer having a polymerizable group described in JP1997-152509A (JP-119-152509A), and a material used for forming the alignment film and the like described in JP2005-097377A, JP2005-099228A, and JP2005-128503A.

In the liquid crystal diffractive lens element 10, the alignment film is suitably used as a so-called photo-alignment film obtained by irradiating a photo-alignment material with polarized light or non-polarized light. That is, in the liquid crystal diffractive lens element 10, a photo-alignment film that is formed by applying a photo-alignment material to the support 20 is suitably used as the alignment film 24.

The irradiation of polarized light can be performed in a direction perpendicular or oblique to the photo-alignment film, and the irradiation of non-polarized light can be performed in a direction oblique to the photo-alignment film.

Preferable examples of the photo-alignment material used for the photo-alignment film that can be used in the present invention include an azo compound described in JP2006-285197A, JP2007-076839A, JP2007-138138A, JP2007-094071A, JP2007-121721A, JP2007-140465A, JP2007-156439A, JP2007-133184A, JP2009-109831A, JP3883848B, and JP4151746B, an aromatic ester compound described in JP2002-229039A, a maleimide and/or alkenyl-substituted nadiimide compound having a photo-alignment unit described in JP2002-265541A and JP2002-317013A, a photocrosslinking silane derivative described in JP4205195B and JP4205198B, photocrosslinking polyimide, photocrosslinking polyamide, and photocrosslinking ester described in JP2003-520878A, JP2004-529220A, and JP4162850B, and a photodimerizable compound, in particular, a cinnamate compound, a chalcone compound, and a coumarin compound described in JP1997-118717A (JP-H9-118717A), JP1998-506420A (JP-H10-506420A), JP2003-505561A, WO2010/150748A, JP2013-177561A, and JP2014-012823A.

Among these, an azo compound, photocrosslinking polyimide, photocrosslinking polyamide, photocrosslinking ester, a cinnamate compound, and a chalcone compound are preferably used.

A thickness of the alignment film is not limited, and may be appropriately set depending on the material for forming the alignment film in a range where required alignment performance is obtained.

The thickness of the alignment film is preferably 0.01 to 5 μm, and more preferably 0.05 to 2 μm.

A method of forming the alignment film is not limited, and various known methods depending on the material for forming the alignment film can be used. As an example, a method of applying the alignment film to the surface of the support 20, drying the alignment film, and then, exposing the alignment film to laser light to form an alignment pattern is used.

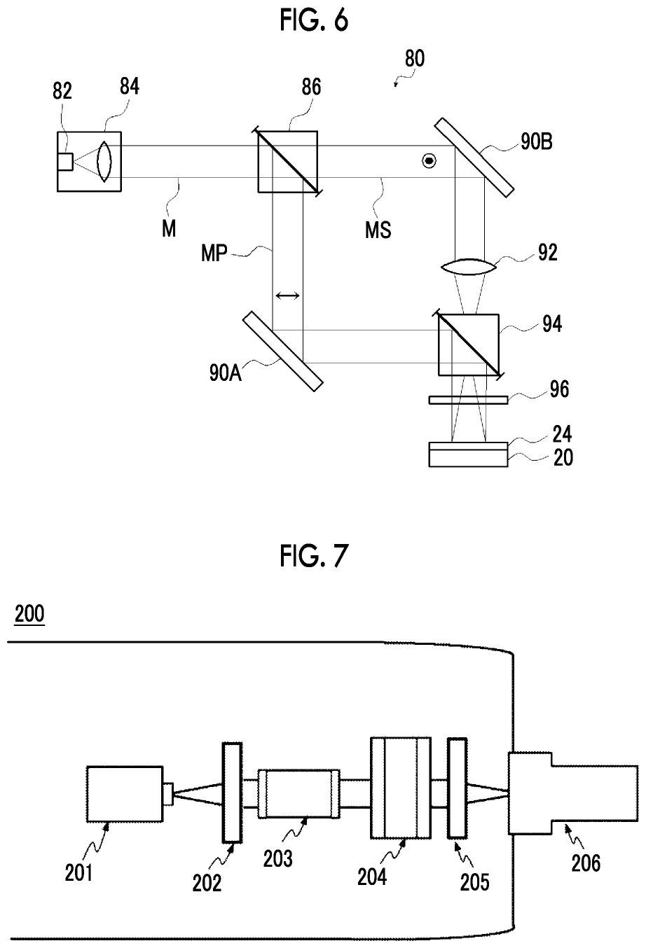

FIG. 6 conceptually shows an example of an exposure device that exposes the alignment film to form the alignment film 24 having the alignment pattern.

An exposure device 80 has a light source 84 that comprises a laser 82, a polarization beam splitter 86 that splits laser light M from the laser 82 into S-polarized light MS and P-polarized light MP, a minor 90A disposed in an optical path of P-polarized light MP and a minor 90B disposed in an optical path of the S-polarized light MS, a lens 92 disposed in the optical path of the S-polarized light MS, a polarization beam splitter 94, and a λ/4 plate 96.

The P-polarized light MP that is split in the polarization beam splitter 86 is reflected by the minor 90A and is incident into the polarization beam splitter 94. On the other hand, the S-polarized light MS that is split in the polarization beam splitter 86 is reflected by the mirror 90B, is collected by the lens 92, and is incident into the polarization beam splitter 94.

The P-polarized light MP and the S-polarized light MS are multiplexed in the polarization beam splitter 94, are converted into right circularly polarized light and left circularly polarized light by the λ/4 plate 96 depending on a polarization direction, and are incident into the alignment film 24 on the support 20.

Here, due to interference between the right circularly polarized light and the left circularly polarized light, a polarization state of light with which the alignment film 24 is irradiated periodically changes to interference fringes. Since an intersecting angle between the left circularly polarized light and the right circularly polarized light changes from the inside toward the outside of a concentric circle, an exposure pattern in which a pitch changes from the inside toward the outside is obtained. With this, in the alignment film 24, a radial (concentric circular) alignment pattern in which an alignment state changes periodically is obtained.

In the exposure device 80, the single period of the liquid crystal alignment pattern in which the optical axis of the liquid crystal compound 30 continuously rotates by 180° along one direction can be controlled by changing a refractive power of the lens 92 (an F-Number of the lens 92), a focal length of the lens 92, a distance between the lens 92 and the alignment film 24, and the like.

The length of the single period of the liquid crystal alignment pattern in one direction in which the optical axis continuously rotates can be changed by adjusting the refractive power of the lens 92 (the F-Number of the lens 92).

Specifically, the length of the single period of the liquid crystal alignment pattern in one direction in which the optical axis continuously rotates can be changed depending on a light spread angle at which light spreads in the lens 92 to interfere parallel light. More specifically, in a case where the refractive power of the lens 92 is weak, light approximates parallel light. Thus, a length A of the single period of the liquid crystal alignment pattern gradually decreases from the inside toward the outside, and the F-Number increases. Conversely, in a case where the refractive power of the lens 92 is strong, the length A of the single period of the liquid crystal alignment pattern rapidly decreases from the inside toward the outside, and the F-Number decreases.

As described above, in the liquid crystal diffractive lens element 10, the alignment film 24 is obtained as a preferred aspect, and is not an essential constituent element.

For example, a configuration can also be made in which, by forming an alignment pattern on the support 20 using a method of rubbing the support 20 or a method of processing the support 20 with laser light or the like, the optically anisotropic layer 26 or the like has the liquid crystal alignment pattern in which the orientation of the optical axis 30A derived from the liquid crystal compound 30 changes while continuously rotating along one direction in a radial shape (concentric circular shape).

<<Optically Anisotropic Layer>>

In the liquid crystal diffractive lens element 10 shown in FIG. 2, the optically anisotropic layer 26 is formed on a surface of the alignment film 24.

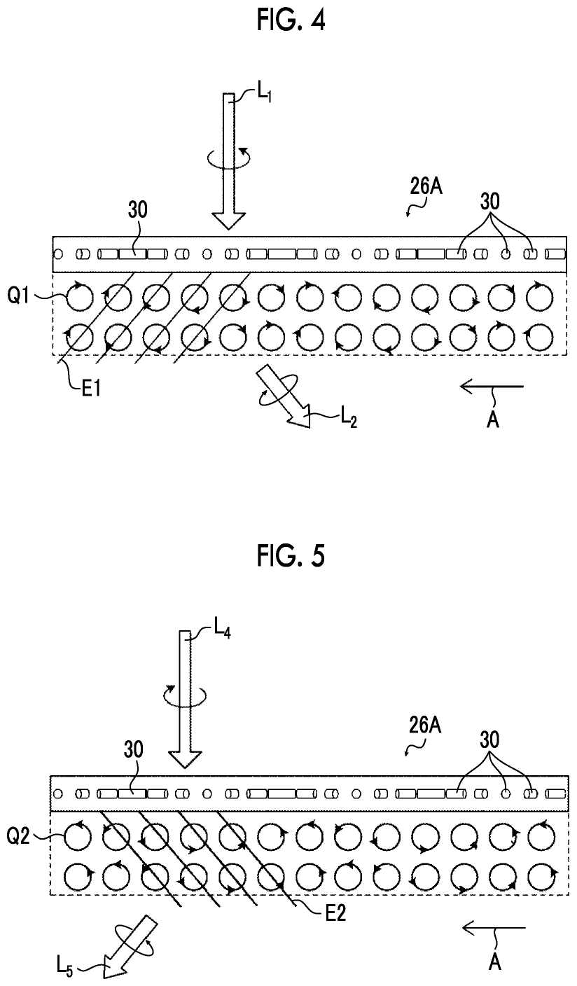

In FIG. 1 (and FIGS. 4 and 5 described below), to simplify the drawing and clarify the configuration of the liquid crystal diffractive lens element 10, only the liquid crystal compound 30 (liquid crystal compound molecules) on the surface of the alignment film 24 in the optically anisotropic layer 26 is shown. Note that, as conceptually shown in FIG. 2, the optically anisotropic layer 26 has a structure in which the aligned liquid crystal compound 30 is laminated like an optically anisotropic layer that is formed of a composition containing a typical liquid crystal compound.

As described above, in the liquid crystal diffractive lens element 10, the optically anisotropic layer 26 is formed of the composition containing the liquid crystal compound.

The optically anisotropic layer 26 has a function as a general λ/2 plate (½ wavelength plate) in a case where a value of in-plane retardation is set to λ/2. That is, the optically anisotropic layer 26 in which the value of in-plane retardation is set to 212 has a function of giving a phase difference of a half wavelength, that is, 180° to two linearly polarized light components that are included in incident light and are perpendicular to each other.

The optically anisotropic layer 26 has the liquid crystal alignment pattern in which the orientation of the optical axis derived from the liquid crystal compound changes while continuously rotating in one direction (the arrow A₁ to arrow A₄ directions, and the like of FIG. 1) in a plane of the optically anisotropic layer, in a radial shape from the inside toward the outside. That is, the liquid crystal alignment pattern of the optically anisotropic layer 26 is a concentric circular pattern that has one direction in which the orientation of the optical axis derived from the liquid crystal compound 30 changes while continuously rotating, in a concentric circular shape from the inside toward the outside.

The optical axis 30A derived from the liquid crystal compound 30 is an axis having a highest refractive index in the liquid crystal compound 30, that is, a so-called slow axis. For example, in a case where the liquid crystal compound 30 is a rod-like liquid crystal compound, the optical axis 30A is along a major axis direction of a rod shape.

In the following description, the optical axis 30A derived from the liquid crystal compound 30 will also be referred to as “the optical axis 30A of the liquid crystal compound 30” or “the optical axis 30A”.

Hereinafter, the optically anisotropic layer 26 will be described referring to an optically anisotropic layer 26A that has a liquid crystal alignment pattern in which the optical axis 30A changes while continuously rotating in one direction indicated by an arrow A, conceptually shown in a plan view of FIG. 3.

Even in the liquid crystal alignment pattern shown in FIG. 1 that has one direction in which the optical axis changes while continuously rotating, in a radial shape (concentric circular shape) from the inside toward the outside, the same optical effects as the liquid crystal alignment pattern shown in FIG. 3 exhibit in regard to one direction in which the optical axis changes while continuously rotating.

In the optically anisotropic layer 26A, liquid crystal compounds 30 are arranged in a two-dimensional manner in a plane parallel to one direction indicated by the arrow A and a Y direction perpendicular to the arrow A direction. In FIGS. 4 and 5 described below, the Y direction is a direction perpendicular to the paper plane.

In the following description, “one direction indicated by the arrow A” will also be simply referred to as “arrow A direction”.

In the optically anisotropic layer 26 shown in FIG. 1, a circumferential direction of the centric circle in the concentric circular liquid crystal alignment pattern corresponds to the Y direction in FIG. 3.

The plan view is a view in a case where the optically anisotropic layer 26A is viewed in a thickness direction (=a laminating direction of each layer (film)) In other words, the plan view is a view in a case where the optically anisotropic layer 26A is viewed from a direction perpendicular to a main surface. The main surface is a largest surface in a sheet-shaped material (plate-shaped material, film, or layer).

In FIG. 3, to clarify the configuration of the liquid crystal diffractive lens element 10, as in FIG. 1, only the liquid crystal compound 30 on the surface of the alignment film 24 is shown. Note that, as shown in FIG. 2, the optically anisotropic layer 26A also has a structure in which the liquid crystal compound 30 is laminated in a thickness direction from the liquid crystal compound 30 on the surface of the alignment film.

The optically anisotropic layer 26A has the liquid crystal alignment pattern in which the orientation of the optical axis 30A derived from the liquid crystal compound 30 changes while continuously rotating along the arrow A direction in a plane of the optically anisotropic layer 26A.

Specifically, “the orientation of the optical axis 30A of the liquid crystal compound 30 changes while continuously rotating in the arrow A direction (predetermined one direction)” means that an angle between the optical axis 30A of each of the liquid crystal compounds 30 arranged in the arrow A direction and the arrow A direction varies depending on a position of the arrow A direction, and an angle between the optical axis 30A and the arrow A direction sequentially changes from θ to θ+180° or θ−180° along the arrow A direction.

A difference between the angles of the optical axes 30A of the liquid crystal compounds 30 adjacent to each other in the arrow A direction is preferably equal to or less than 45°, more preferably equal to or less than 15°, and still more preferably less than 15°. On the other hand, in regard to the liquid crystal compounds 30 that form the optically anisotropic layer 26A, the liquid crystal compounds 30 having the same orientation of the optical axis 30A are arranged at regular intervals in the Y direction perpendicular to the arrow A direction, that is, the Y direction perpendicular to one direction in which the optical axis 30A continuously rotates.

In other words, in the liquid crystal compounds 30 that form the optically anisotropic layer 26A, the angle between the orientation of the optical axis 30A and the arrow A direction is the same in the liquid crystal compounds 30 arranged in the Y direction.

In the optically anisotropic layer 26A shown in FIG. 1, regions having the same orientations of the optical axes 30A are formed in annular shapes concentric to each other.

In the liquid crystal alignment pattern in which the optical axis 30A continuously rotates toward one direction, the length (distance) over which the optical axis 30A of the liquid crystal compound 30 rotates by 180° is set as the length Λ of the single period in the liquid crystal alignment pattern.

That is, in a case of the optically anisotropic layer 26A shown in FIG. 3, the length (distance) over which the optical axis 30A of the liquid crystal compound 30 rotates by 180° in the arrow A direction in which the orientation of the optical axis 30A changes while continuously rotating in a plane is set as the length Λ of the single period in the liquid crystal alignment pattern. In other words, the length of the single period in the liquid crystal alignment pattern is defined by a distance between θ to θ+180° that is a range of the arrow between the optical axis 30A of the liquid crystal compound 30 and the arrow A direction.

That is, a distance between centers in the arrow A direction of two liquid crystal compounds 30 having the same angle with respect to the arrow A direction is set as the length Λ of the single period. Specifically, as shown in FIG. 3, a distance between centers in the arrow A direction of two liquid crystal compounds 30 in which the arrow A direction matches the optical axis 30A is set as the length Λ of the single period.

In the following description, the length Λ of the single period will also be referred to as “single period Λ”.

In the optically anisotropic layer 26A (optically anisotropic layer 26), the liquid crystal alignment pattern of the optically anisotropic layer repeats the single period Λ in the arrow A direction, that is, one direction in which the orientation of the optical axis 30A changes while continuously rotating.

In the liquid crystal diffractive lens element 10 that has the liquid crystal alignment pattern in which the optical axis 30A continuously rotates, in a radial shape (concentric circular shape) and is used in the communication device of the present invention, the single period Λ in the optically anisotropic layer 26A sequentially decreases from the inside (center) toward the outside.

As described above, in the optically anisotropic layer 26A, the angle between the optical axis 30A and the arrow A direction (one direction in which the orientation of the optical axis of the liquid crystal compound 30 rotates) is the same in the liquid crystal compounds arranged in the Y direction. Regions where the liquid crystal compounds 30 in which the angle between the optical axis 30A and the arrow A direction is the same are disposed in the Y direction are referred to as regions R.

In this case, it is preferable that a value of in-plane retardation (Re) in each region R is a half wavelength, that is, λ/2. The in-plane retardation is calculated by a product of a difference Δn in refractive index generated by refractive index anisotropy of the region R and the thickness of the optically anisotropic layer. Here, the difference in refractive index generated by refractive index anisotropy of the region R in the optically anisotropic layer is a difference in refractive index that is defined by a difference between a refractive index of a direction of an in-plane slow axis of the region R and a refractive index of a direction perpendicular to the direction of the slow axis. That is, the difference Δn in refractive index generated by refractive index anisotropy of the region R is equal to a difference between a refractive index of the liquid crystal compound 30 in a direction of the optical axis 30A and a refractive index of the liquid crystal compound 30 in a direction perpendicular to the optical axis 30A in a plane of the region R. That is, the different Δn in refractive index is equal to the difference in refractive index of the liquid crystal compound.

In the liquid crystal diffractive lens element 10 that has the liquid crystal alignment pattern in which the optical axis 30A continuously rotates toward one direction, in a radial shape, and is used in the communication device of the present invention, in the optically anisotropic layer 26A shown in FIG. 1, regions that are formed in annular shapes concentric to each other and have the same orientation of the optical axis 30A correspond to the regions R in FIG. 3.

In a case where circularly polarized light is incident into such an optically anisotropic layer 26A, light is refracted, and the direction of the circularly polarized light is converted.

The action is conceptually shown in FIGS. 4 and 5. In the optically anisotropic layer 26A, a value of a product of the difference in refractive index of the liquid crystal compound and the thickness of the optically anisotropic layer is λ/2.

As described above, even the liquid crystal diffractive lens element 10 that has the liquid crystal alignment pattern in which the optical axis 30A continuously rotates toward one direction, in a radial shape, and that is used in the communication device of the present invention exhibits the completely same reaction.

As shown in FIG. 4, in a case where the value of the product of the difference in refractive index of the liquid crystal compound of the optically anisotropic layer 26A and the thickness of the optically anisotropic layer is λ/2, and in a case where incident light L₁ that is left circularly polarized light is incident into the optically anisotropic layer 26A, the incident light L₁ passes through the optically anisotropic layer 26A to be given a phase difference of 180°, and transmitted light L₂ is converted into right circularly polarized light.

In a case where the incident light L₁ passes through the optically anisotropic layer 26A, an absolute phase of the incident light L₁ changes depending on the orientation of the optical axis 30A of each of the liquid crystal compounds 30. In this case, since the orientation of the optical axis 30A changes while rotating along the arrow A direction, an amount of change in absolute phase of the incident light L₁ varies depending on the orientation of the optical axis 30A. Since the liquid crystal alignment pattern formed in the optically anisotropic layer 26A is a pattern that is periodic in the arrow A direction, as shown in FIG. 4, the incident light L₁ passing through the optically anisotropic layer 26A is given an absolute phase Q1 that is periodic in the arrow A direction corresponding to the orientation of each of the optical axes 30A. With this, an equiphase surface E1 that is tilted in a direction opposite to the arrow A direction is formed.

For this reason, the transmitted light L₂ is refracted (diffracted) to be tilted toward a direction perpendicular to the equiphase surface E1 and travels in a direction different from a traveling direction of the incident light L₁. In this way, the incident light L₁ of the left circularly polarized light is converted into the transmitted light L₂ of right circularly polarized light that is tilted by a predetermined angle in the arrow A direction with respect to an incidence direction.

On the other hand, as conceptually shown in FIG. 5, in a case where the value of the product of the difference in refractive index of the liquid crystal compound of the optically anisotropic layer 26A and the thickness of the optically anisotropic layer is λ/2, and in a case where incident light L₄ of right circularly polarized light is into the optically anisotropic layer 26A, the incident light L₄ passes through the optically anisotropic layer 26A to be given a phase difference of 180° and is converted into transmitted light L₅ of left circularly polarized light.

In a case where the incident light L₄ passes through the optically anisotropic layer 26A, an absolute phase of the incident light L₄ changes depending on the orientation of the optical axis 30A of each of the liquid crystal compounds 30. In this case, since the orientation of the optical axis 30A changes while rotating along the arrow A direction, an amount of change in absolute phase of the incident light L₄ varies depending on the orientation of the optical axis 30A. Since the liquid crystal alignment pattern formed in the optically anisotropic layer 26A is a pattern that is periodic in the arrow A direction, as shown in FIG. 5, the incident light L₄ passing through the optically anisotropic layer 26A is given an absolute phase Q2 that is periodic in the arrow A direction corresponding to the orientation of each of the optical axes 30A.

Here, since the incident light L₄ is right circularly polarized light, the absolute phase Q2 that is periodic in the arrow A direction corresponding to the orientation of the optical axis 30A is opposite to the incident light L₁ that is the left circularly polarized light. As a result, in the incident light L₄, an equiphase surface E2 that is tilted in the arrow A direction opposite to that of the incident light L₁ is formed.

For this reason, the incident light L₄ is refracted to be tilted toward a direction perpendicular to the equiphase surface E2 and travels in a direction different from a traveling direction of the incident light L₄. In this way, the incident light L₄ is converted into transmitted light L₅ of left circularly polarized light that is tilted by a predetermined angle in a direction opposite to the arrow A direction with respect to an incidence direction.

In the optically anisotropic layer 26A, it is preferable that the value of in-plane retardation of each of a plurality of regions R is a half wavelength. It is preferable that an in-plane retardation Re (550)=Δn₅₅₀×d of each of a plurality of regions R of the optically anisotropic layer 26A with respect to incident light having a wavelength of 550 nm is within a range defined by Expression (1) described below. Here, Δn₅₅₀ is a difference in refractive index generated by refractive index anisotropy of the region R in a case where the wavelength of incident light is 550 nm, and d is the thickness of the optically anisotropic layer 26A.

200 nm≤Δn₅₅₀×d≤350 nm (1)

The optically anisotropic layer 26A functions as a so-called λ/2 plate. Note that the present invention includes an aspect where, in a case where the support 20 and the alignment film 24 are provided, a laminate comprising the support 20 and the alignment film 24 integrally functions as a λ/2 plate.

Here, in the optically anisotropic layer 26A, angles of refraction of transmitted light L₂ and L₅ can be adjusted by changing the single period A of the formed liquid crystal alignment pattern. Specifically, as the single period A of the liquid crystal alignment pattern decreases, light components passing through the liquid crystal compounds 30 adjacent to each other more strongly interfere with each other. Therefore, the transmitted light L₂ and L₅ can be more largely refracted.

Angle of refraction of the transmitted light L₂ and L₅ with respect to the incident light L₁ and L₄ vary depending on the wavelengths of the incident light L₁ and L₄ (transmitted light L₂ and L₅). Specifically, as the wavelength of incident light increases, transmitted light is largely refracted. That is, in a case where incident light is red light, green light, and blue light, the red light is refracted to the highest degree, and the blue light is refracted to the lowest degree.

The rotation direction of the optical axis 30A of the liquid crystal compound 30 that rotates along the arrow A direction is reversed, whereby the direction of refraction of transmitted light can be revered.

As described above, in the communication device of the present invention, the optically anisotropic layer 26A of the liquid crystal diffractive lens element 10 has the liquid crystal alignment pattern in which the optical axis 30A rotates toward one direction, and the single period Λ of the liquid crystal alignment pattern gradually decreases from the inside (center) toward the outside.

Accordingly, the rotation direction of the optical axis 30A from the inside toward the outside is set and a degree of gradual decrease of the length of the single period Λ of the liquid crystal alignment pattern is adjusted depending on a wavelength, a polarization state, or the like of incident light such that light is refracted toward the center of the liquid crystal diffractive lens element 10, whereby a degree of collection of light toward the center (optical axis) of the liquid crystal diffractive lens element 10 can be adjusted.

That is, the length of the single period Λ of the liquid crystal alignment pattern largely gradually decreases, whereby the liquid crystal diffractive lens element 10 can be made to act as a condenser lens (convex lens). The degree of gradual decrease of the length of the single period Λ of the liquid crystal alignment pattern is moderated, whereby the liquid crystal diffractive lens element 10 can be made to act as a collimating lens.

The optically anisotropic layer 26A is formed of a liquid crystal composition containing a rod-like liquid crystal compound or a disc-like liquid crystal compound, and an optical axis of the rod-like liquid crystal compound or an optical axis of the disc-like liquid crystal compound has a liquid crystal alignment pattern aligned as described above.

The alignment film 24 having an alignment pattern corresponding to the above-described liquid crystal alignment pattern is formed on the support 20, and a liquid crystal composition is applied to the alignment film 24 and cured, whereby an optically anisotropic layer formed of a cured layer of the liquid crystal composition can be obtained.

The liquid crystal composition for forming the optically anisotropic layer 26A contains a rod-like liquid crystal compound or a disc-like liquid crystal compound, and may further contain other components, such as a leveling agent, an alignment control agent, a polymerization initiator, and an alignment assistant.

It is preferable that the optically anisotropic layer 26A has a wide range with respect to the wavelength of incident light and is formed of using a liquid crystal material having reverse birefringence dispersion. It is also preferable that the optically anisotropic layer is made to have a substantially wide range with respect to the wavelength of incident light by giving a twisted component to the liquid crystal composition or laminating different phase different layers. For example, in the optically anisotropic layer 26A, a method of realizing a λ/2 plate having a wide-range pattern by laminating two liquid crystal layers having different twisted directions is disclosed in JP2014-089476A or the like, and can be preferably used in the present invention.

—Rod-Like Liquid Crystal Compound—

Preferable examples of the rod-like liquid crystal compound include an azomethine compound, an azoxy compound, a cyanobiphenyl compound, a cyanophenyl ester compound, a benzoate compound, a phenyl cyclohexanecarboxylate compound, a cyanophenylcyclohexane compound, a cyano-substituted phenylpyrimidine compound, an alkoxy-substituted phenylpyrimidine compound, a phenyldioxane compound, a tolan compound, or an alkenylcyclohexylbenzonitrile compound. As the rod-like liquid crystal compound, not only the above-described low molecular weight liquid crystal molecules but also high molecular weight liquid crystal molecules can be used.

In the optically anisotropic layer 26A, It is preferable that the alignment of the rod-like liquid crystal compound is immobilized by polymerization. Examples of polymerizable rod-like liquid crystal compound include compounds described in Makromol. Chem., Vol. 190, p. 2255 (1989), Advanced Materials, Vol. 5, p. 107 (1993), U.S. Pat. Nos. 4,683,327A, 5,622,648A, 5,770,107A, WO95/022586A, WO95/024455A, WO97/000600A, WO98/023580A, WO98/052905A, JP1989-272551A (JP-H1-272551A), JP1994-016616A (JP-H6-016616A), JP1995-110469A (JP-H7-110469A), JP1999-080081A (JP-H11-080081A), and JP2001-064627. As the rod-like liquid crystal compound, for example, compounds described in JP1999-513019A (JP-H11-513019A) and JP2007-279688A can be preferably used.

—Disc-Like Liquid Crystal Compound—

As the disc-like liquid crystal compound, for example, compounds described in JP2007-108732A and JP2010-244038A can be preferably used.

In a case where the disc-like liquid crystal compound is used in the optically anisotropic layer, the liquid crystal compound 30 rises in the thickness direction in the optically anisotropic layer, and the optical axis 30A derived from the liquid crystal compound is defined as an axis perpendicular to a disc plane, that is, a so-called fast axis.

The liquid crystal diffractive lens element 10 having such a optically anisotropic layer 26A has a sheet shape, and does not have a convexoconcave surface of a ball lens, a hemispherical lens, or a microlens.

The liquid crystal diffractive lens element 10 has a thin thickness of 1 to 100 μm.

Accordingly, the liquid crystal diffractive lens element 10 is used as a lens element, whereby advantages of achieving a reduction in size of the communication device of the present invention (a device that configures the communication device of the present invention) and a reduction of a mounting space.

Such a liquid crystal diffractive lens element can be used in various devices that configure an optical communication system. Examples of devices that configure the optical communication system include an optical transmitter optical assembly including a wavelength locker, a wavelength demultiplexer, an optical displacer, and an optical coupling system including an optical displacer, and an optical switching system.

In each of the devices that configure the optical communication system, a λ/4 plate (¼ wavelength plate) and a circularly polarizing plate composed of a polarizer and a λ/4 plate may be provided upstream of the above-described liquid crystal diffractive lens element as an optical member that converts light into circularly polarized light as necessary.

Here, in the present invention, in a case where there is no particular annotation, upstream and downstream are upstream and downstream in a traveling direction of light.

FIG. 7 conceptually shows an optical transmitter optical assembly that includes a wavelength locker using such a liquid crystal diffractive lens element, as an example of a preferable example of a device that configures the optical communication device of the present invention.

An optical transmitter optical assembly 200 shown in FIG. 7 has a laser 201, a collimating lens 202, an optical isolator 203, an etalon 204, a condenser lens 205, and a ferrule 206. Such members are disposed linearly and form the optical transmitter optical assembly 200.

In the example shown in the drawing, the collimating lens 202, the etalon 204, and the condenser lens 205 configure a wavelength locker unit (wavelength locker).

In the optical transmitter optical assembly 200, the collimating lens 202 is the above-described liquid crystal diffractive lens element 10.

In the optical transmitter optical assembly 200 shown in FIG. 7, the members other than the collimating lens 202 are known optical members (optical elements) that are used in a known optical transmitter optical assembly and a known wavelength locker.

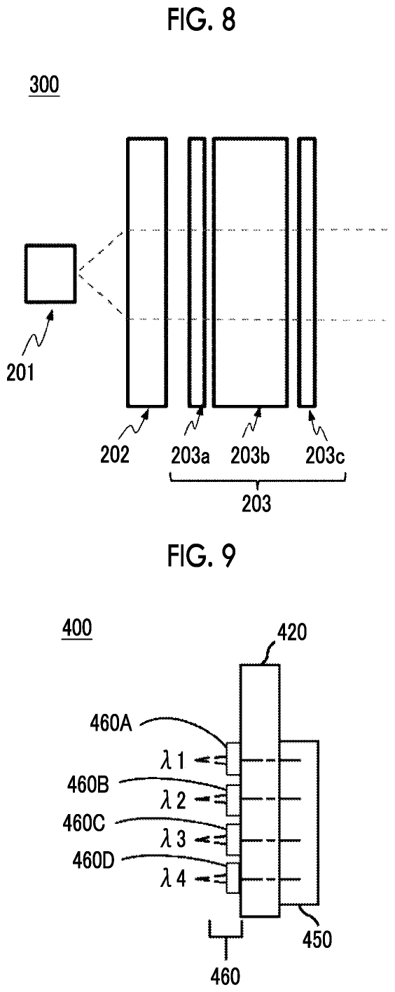

Examples of the laser 201 include a distributed feedback laser. In the following description, a distributed feedback laser is also referred to as a DFB laser. The DFB is an abbreviation for “Distributed Feedback”. An example of an optical isolator 203 will be illustrated in FIG. 8 and will be described below.

In the optical transmitter optical assembly 200 shown in FIG. 7, laser light emitted from the laser 201 is collimated by the collimating lens 202.

The collimated light is transmitted through the optical isolator 203 that transmits only light traveling in a forward direction and blocks light in a backward direction and is filtered by the etalon 204, and is converted into predetermined narrowband light.

The narrowband light is collected by the condenser lens 205, is incident into the ferrule 206, and is supplied to an optical fiber that is provided to supply (communicate) light to an optical element on a downstream side.

The etalon 204 is an optical filter that transmits only predetermined narrowband light. As well known in the art, collimated light (parallel light) needs to be incident into the etalon 204. Accordingly, emitted light from the laser 201 having a beam spread of a given level or higher in principle, such as a DFB laser, cannot be incident into the etalon 204. Accordingly, the collimating lens 202 that collimates emitted light of the laser 201 is required between the laser 201 and the etalon 204.

In addition, in a case where light reflected from the etalon 204 and retroreflected light from the ferrule 206 and the optical fiber (not shown) connected to the ferrule 206 loop inside the optical transmitter optical assembly 200, the performance of the optical transmitter optical assembly 200 is degraded. For this reason, the optical isolator 203 is provided between the collimating lens 202 and the etalon 204.

As a preferable aspect, the condenser lens 205 is provided to collect light emitted from the etalon 204 and make the collected light be incident into the ferrule 206. Accordingly, in the wavelength locker unit, the condenser lens 205 is not an essential constituent element. In the optical transmitter optical assembly 200 that configures the optical communication device of the present invention, the above-described liquid crystal diffractive lens element 10 may be used as the condenser lens 205.

The optical members that configure such an optical transmitter optical assembly 200 are sensitive to a change of an ambient environment. For this reason, such optical members are sealed airtight excluding a part (connection portions with other optical members) of the ferrule 206.

Here, as described above, collimated light needs to be incident into the etalon 204. For this reason, the optical transmitter optical assembly 200 disposes the collimating lens 202 upstream of the etalon 204 to make the collimated light be incident into the etalon 204.

In the related art, a ball lens, a semispherical lens, an aspherical lens, or the like is used as the collimating lens 202. For this reason, the optical transmitter optical assembly 200 has a long total length, and the number of steps and cost for airtight sealing increase.

In contrast, the optical transmitter optical assembly 200 (wavelength locker unit (wavelength locker)) shown in FIG. 7 uses the above-described liquid crystal diffractive lens element 10 as the collimating lens 202. As described above, the liquid crystal diffractive lens element 10 has a thin sheet shape. For this reason, according to the present invention, the wavelength locker, that is, the optical transmitter optical assembly 200 can be reduced in size, and benefits are provided even in terms of airtight sealing.

The above-described liquid crystal diffractive lens element 10 has a thin sheet shape. For this reason, the optical transmitter optical assembly 200 that uses the liquid crystal diffractive lens element 10 as the collimating lens 202 can integrate the collimating lens 202 and the optical isolator 203.

The collimating lens 202 and the optical isolator 203 are integrated, for example, a mounting size in the wavelength locker unit can be further reduced, and the number of manufacturing steps can be reduced with a reduction in the number of parts.

FIG. 8 conceptually shows an example of a lens-optical isolator integrated element 300 in which the collimating lens 202 (liquid crystal diffractive lens element) and the optical isolator 203 are integrated.

In the lens-optical isolator integrated element 300, the collimating lens 202 and the optical isolator 203 are integrated.

As shown in FIG. 8, as an example, the optical isolator 203 can be configured of a first polarizer 203a, an azimuth rotator 203b, and a second polarizer 203c. In the optical transmitter optical assembly 200 of the present invention, the optical isolator 203 is not limited thereto, and various known optical isolators can be used as described above.

As the polarizer, various known polarizers, such as a wire grid, a Glan-Taylor polarizer, and a resin polarizer, can be used.

As the azimuth rotator 203b, various known azimuth rotators, such as an azimuth rotator using an inorganic material, such as yttrium-aluminum-garnet (YAG), an organic material, or a liquid crystal material, can be used. In particular, an azimuth rotator containing a liquid crystal material with a fixed twisted alignment is particularly preferably used since such an azimuth rotator has a thin thickness of 1 to 100 μm and remarkably contributes to a reduction in size of the member.

A condenser lens element may be provided on a light emission side of the lens-optical isolator integrated element 300 as necessary.

In this case, it is desirable that the above-described liquid crystal diffractive lens element 10 is used as the condenser lens element.

A method of integrating the collimating lens 202 and the optical isolator 203 is not limited, and various known methods that are used to integrate (bond) optical members needed for securing sufficient light transmittance in an optical device (optical device) can be used.

Examples of the methods include integration using a bonding layer.

As the bonding layer, any layers formed of various known materials can be used as long as the layers bond objects to be bonded. The bonding layer may be a layer formed of an adhesive, a layer formed of a pressure sensitive adhesive, or a layer formed of a material having features of both an adhesive and a pressure sensitive adhesive. The adhesive is a bonding agent that has fluidity in bonding and becomes solid after bonding. The pressure sensitive adhesive is a bonding agent that is a gel-like (rubber-like) soft solid in bonding and is maintained in a gel-like state even after bonding.

Accordingly, as the bonding layer, known bonding layers that are used to bond optical members in an optical device, an optical element, or the like, such as an optically transparent adhesive (optical clear adhesive (OCA)), an optically transparent double-sided tape, and ultraviolet curable resin, may be used.

A bonding layer used for bonding each element, a housing, and the like are not shown in FIG. 8, but can be appropriately added along the purposes of the present invention.

In this case, examples of the bonding layer include the above-described layers.

FIGS. 9 to 11 conceptually show an example of a wavelength demultiplexer using the liquid crystal diffractive lens element 10, as a preferable example of a device that configures the optical communication device of the present invention.

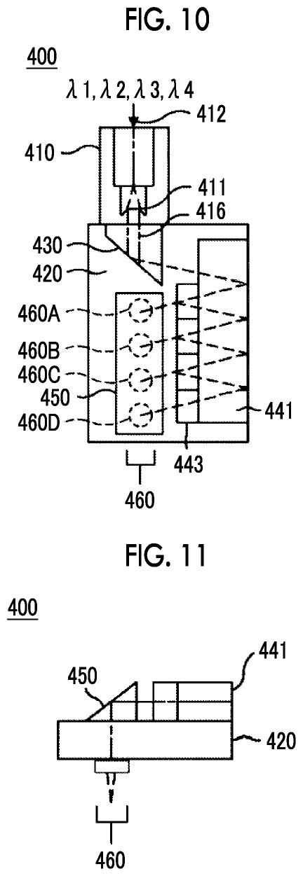

FIG. 9 is a first side view of a wavelength demultiplexer 400, FIG. 10 is a front view of the wavelength demultiplexer 400, and FIG. 11 is a second side view of the wavelength demultiplexer 400.

Specifically, FIG. 9 is a diagram in a case where the wavelength demultiplexer 400 is viewed from a horizontal direction on the paper plane in FIG. 10, and FIG. 11 is a diagram in a case where the wavelength demultiplexer 400 is viewed from a downward direction on the paper plane in FIG. 10.

The wavelength demultiplexer 400 of the example shown in the drawing has a base 420, and a socket 410, a collimating lens 411, a reflector 430, a demultiplexer block 441, a narrowband wavelength selective filter 443, a folding prism 450, and a condenser lens array 460 that are provided on the base 420.

The condenser lens array 460 has four condenser lenses 460A to 460D. The condenser lenses are the above-described liquid crystal diffractive lens element 10.

In the wavelength demultiplexer 400 of the example shown in the drawing, to simply the drawing and to clarify the configuration, a wavelength demultiplexer that deals with four narrowband wavelengths (λ1 to λ4) are shown; however, the present invention is not limited thereto, and a wavelength demultiplexer that can deal with more wavelength ranges may be provided.

In the wavelength demultiplexer 400 shown in FIGS. 9 to 11, members other than the condenser lenses 460A to 460D are known optical members that are used in a known wavelength demultiplexer.

In the wavelength demultiplexer 400 of the example shown in the drawing, the base 420 is a rectangular plate-shaped member that is formed of a material having sufficient transmittance with respect to light subjected to wavelength separation.

In the wavelength demultiplexer 400, the socket 410, the collimating lens 411, the reflector 430, the demultiplexer block 441, the narrowband wavelength selective filter 443, and the folding prism 450 are provided on one main surface (front surface) of the base 420, and the condenser lens array 460 is provided on the other main surface (back surface) of the base 420.

In the wavelength demultiplexer 400, wavelength-multiplexed light 412 including four wavelengths (λ1 to λ4) is supplied, for example, by an optical fiber (not shown) inserted into the socket 410.

The supplied light is collimated by the collimating lens 411 to be converted into parallel light 416, is reflected by the reflector 430, and is incident into the demultiplexer block 441. The reflector 430 is, for example, a prism.

Light incident into the demultiplexer block 441 is repeatedly reflected in the demultiplexer block 441, and is incident into the narrowband wavelength selective filter 443.

The narrowband wavelength selective filter 443 has four narrowband band-pass filters. The band-pass filters transmit light components of the wavelength λ1, the wavelength λ2, the wavelength λ3, and the wavelength λ4, respectively. Accordingly, light that is repeatedly reflected in the demultiplexer block 441 and is incident into the narrowband wavelength selective filter 443 is transmitted through the band-pass filters corresponding to the wavelengths and is split into light components of the respective wavelengths of the wavelength λ1, the wavelength λ2, the wavelength λ3, and the wavelength λ4.

Light subjected to wavelength separation in the narrowband wavelength selective filter 443 is reflected such that an optical path is folded by the folding prism 450, is transmitted through the base 420, reaches a back surface side, and is incident into the condenser lens array 460.

As described above, the condenser lens array 460 has the four condenser lenses 460A to 460D.

Each condenser lens in the condenser lens array 460 is disposed at a position corresponding to the narrowband band-pass filter in the narrowband wavelength selective filter 443 that transmits light of a corresponding wavelength. As an example, the condenser lens 460A corresponds to the light component of the wavelength λ1, the condenser lens 460B corresponds to the light component of the wavelength λ2, the condenser lens 460C corresponds to the light component of the wavelength λ3, and the condenser lens 460D corresponds to the light component of the wavelength 2A.

Accordingly, the light components of the wavelength λ1, the wavelength λ2, the wavelength λ3, and the wavelength λ4 separated by the narrowband wavelength selective filter 443 are collected by the condenser lens 460A, the condenser lens 460B, the condenser lens 460C, and the condenser lens 460D, respectively, and are incident into an optical member on a downstream side, for example, the optical fiber.

In such a wavelength demultiplexer, hitherto, a ball lens, a semispherical lens, an aspherical lens, or the like is used as the condenser lenses 460A to 460D. Note that the ball lens or the like has a structure of protruding from a side surface of the wavelength demultiplexer, and has restrictions in terms of mounting.

In contrast, the wavelength demultiplexer 400 of the present invention uses the above-described liquid crystal diffractive lens element 10 as the condenser lenses 460A to 460D. As described above, the liquid crystal diffractive lens element has a thin sheet shape. For this reason, in the wavelength demultiplexer 400 of the present invention, a side surface is flat, whereby a degree of freedom of mounting layout increases, a mounting space can be reduced, and it is advantageous to device design.

The wavelength demultiplexer 400 of the example shown in the drawing has the folding prism 450, and makes light subjected to wavelength separation by the demultiplexer block 441 and the narrowband wavelength selective filter 443 be transmitted through the base 420 and incident into the condenser lens array 460.

Note that the wavelength demultiplexer of the present invention is not limited thereto, and various configurations can be used.

As an example, the wavelength demultiplexer of the present invention may not have the folding prism 450, may provide the condenser lens array 460 on the same surface of the base 420 as the demultiplexer block 441 and the like, and may make light subjected to wavelength separation by the demultiplexer block 441 and the narrowband wavelength selective filter 443 be directly incident into the condenser lens array 460.

The same applies to the reflector 430 that is provided on an incidence side. That is, in the wavelength demultiplexer of the present invention, the reflector 430 may not be provided, and light supplied from the socket 410 may be made to be directly incident into the demultiplexer block 441.

In the optical communication device of the present invention, the wavelength demultiplexer 400 can also have a configuration in which the condenser lens array 460 side is an incidence side of light and a connector 414 side is an emission side of light. With this, the wavelength demultiplexer 400 can be used as an optical multiplexer.

That is, a plurality of optical transmitter optical assemblies 200 including the wavelength locker shown in FIG. 7 described above are provided, and the wavelengths of light components emitted from the respective optical transmitter optical assemblies 200 are different. In addition, light emitted from each optical transmitter optical assembly 200 is made to be incident from the condenser lens array 460, whereby signal light in a wavelength multiplex mode can be made to be incident into the optical fiber mounted to the socket 410 from the socket 410 side.

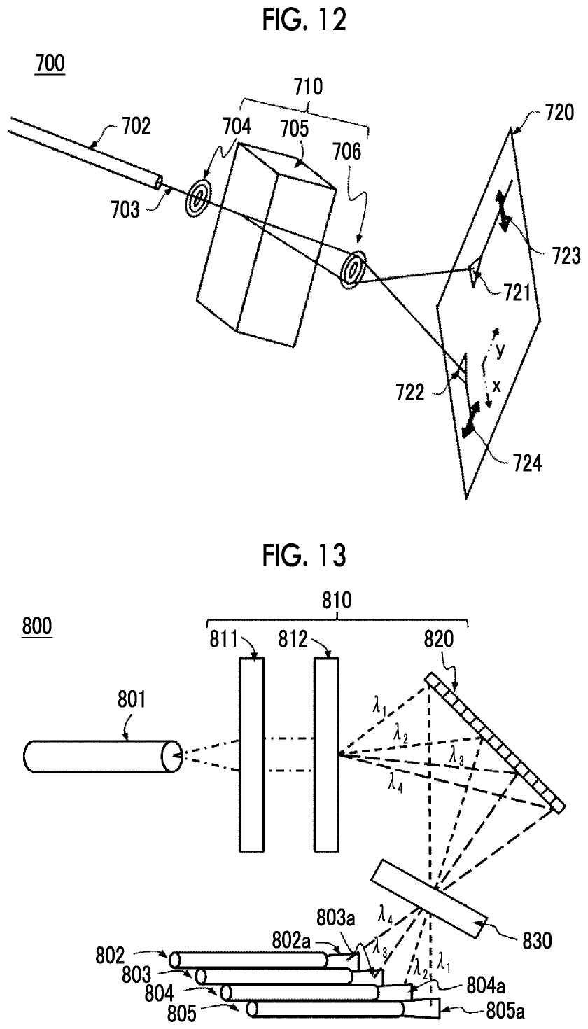

FIG. 12 conceptually shows an example of an optical displacer using the liquid crystal diffractive lens element 10 and an optical coupling system including the optical displacer, as a preferable example of a device that configures the optical communication device of the present invention.

An optical displacer 710 shown in FIG. 12 is for polarization separation of light, and has an incidence-side lens element 704, a birefringent plate 705, and an emission-side lens element 706. The emission-side lens element 706 is provided as necessary.

In the optical displacer 710, the incidence-side lens element 704 is the above-described liquid crystal diffractive lens element 10. The incidence-side lens element 704 acts as a collimating lens.

In the optical displacer 710 and an optical coupling system 700 shown in FIG. 12, members other than the incidence-side lens element 704 are known optical members that are used in a known optical displacer and a known optical coupling system.

For example, as the birefringent plate 705, various known phase difference plates can be used. Specifically, the birefringent plate 705 can be formed of an inorganic birefringent material, such as yttrium vanadate (YVO₄) crystal, barium borate (α-BBO) crystal, calcite crystal, or rutile (TiO₂) crystal, or an organic birefringent material.

In the optical displacer 710, light 730 that is emitted from an optical fiber 702 includes, for example, S-polarized light and P-polarized light.

The light 730 is collimated (converted into parallel light) by the incidence-side lens element 704 that acts as a collimating lens, and is separated into S-polarized light and P-polarized light by the birefringent plate 705.

The separated S-polarized light and P-polarized light are adjusted in optical path by the emission-side lens element 706 that is provided as necessary, and incident into an optical member on a downstream side, in the example shown in the drawing, a photonic device 720.

In the present invention, the above-described liquid crystal diffractive lens element 10 may be used as the emission-side lens element 706.

For ideal beam separation (polarization separation) in the birefringent plate 705, the light 703 that is incident into at least the birefringent plate 705 needs to be parallel light. Accordingly, for example, it is not preferable that light that is emitted from the DFB laser, an optical fiber end, or the like and has a spread is incident into the birefringent plate 705 as it is.

For this reason, in the optical displacer, the collimating lens is provided upstream of the birefringent plate that is for polarization separation, and light that is collimated and converted into parallel light is made to be incident into the birefringent plate.

In an optical displacer of the related art, a ball lens, a semispherical lens, an aspherical lens, or the like is used as the collimating lens. Such lenses have a problem in that a large mounting space is required.

In contrast, the optical displacer 710 of the present invention uses the above-described liquid crystal diffractive lens element 10 as the incidence-side lens element 704 that acts as the collimating lens. As described above, the liquid crystal diffractive lens element has a thin sheet shape. For this reason, in the optical displacer 710 of the present invention, a mounting space can be reduced. In addition, the incidence-side lens element 704 (liquid crystal diffractive lens element) having a thin sheet shape can also be provided integrally on the surface of the birefringent plate 705 like the integrated element shown in FIG. 3. The integrated configuration has advantages in that a reduction of the mounting space is achieved, alignment with an incidence optical axis is facilitated, and mounting work is more simplified.

The above-described optical displacer 710 is combined with the photonic device 720 including the optical fiber 702 and a plurality of grating couplers 721 and 722, whereby the optical coupling system 700 that can deal with a polarization multiplex mode can be configured. The optical coupling system functions as a polarization multiplex mode optical receiver.

That is, the light 703 including P-polarized light and S-polarized light emitted from the optical fiber 702 is subjected to polarization separation by the optical displacer 710 as described above. Polarized light 723 and polarized light 724 that are polarized light components perpendicular to each other are incident into the photonic device 720 and coupled by the grating coupler 721 and the grating coupler 722, whereby a polarization multiplexed multichannel system is realized. The photonic device 720 has a photoelectric conversion element, and S-polarized light and P-polarized light incident into the photonic device 720 are photoelectrically converted into an electrical signal.

FIG. 13 conceptually shows an example of an optical switching system using the above-described liquid crystal diffractive lens element 10 and an optical coupling system including the optical switching system, as a preferable example of a device that configures the optical communication device of the present invention.

An optical switching system 810 has a collimating lens 811, a spectral element 812, and a spatial modulator 820. The collimating lens 811 is the above-described liquid crystal diffractive lens element 10.

In the optical switching system 810 and an optical coupling system 800 shown in FIG. 13, members other than the collimating lens 811 are known optical members that are used in a known optical switching system and a known optical coupling system.

For example, as the spectral element 812, a blazed diffraction grating, a prism, a hologram element, a liquid crystal diffraction element, or the like can be used. The spectral element 812 may be a polarization diffraction element in which a diffraction structure is formed of structural birefringence described in “Erez Hasman et al., Polarization dependent focusing lens by use of quantized Pancharatnm-Berry phase diffractive optics, Applied Physics Letters, Volume 82, Number 3 pp. 328-330”.

A hologram element and a liquid crystal diffraction element are preferably used in that a thin and small-sized element can be created, and a liquid crystal diffraction element is more preferably used in that a wavelength resolution is high. As such a liquid crystal diffraction element, for example, a polarization diffraction element in which a diffraction structure is formed of a birefringent material described in JP5276847B, and a cholesteric liquid crystal layer formed by fixing a cholesteric liquid crystalline phase can be used.

On the other hand, the spatial modulator 820 may be any of a transmissive type or a reflective type, and a liquid crystal on silicon (LCOS), a liquid crystal cell (LC cell), a digital micromirror device (DMD), or the like can be used. From a small optical loss and excellent optical coupling efficiency, LCOS or DMD is preferably used.

For example, an optical fiber 801 is provided as an incidence-side optical fiber, and signal light of multiplexed wavelengths including four wavelengths (λ1 to λ4) is emitted from the optical fiber 801.

The signal light that is emitted from the optical fiber 801 and is converted into parallel light through the collimating lens 811 is subjected to wavelength separation into light components of the wavelength λ1, the wavelength λ2, the wavelength λ3, and the wavelength λ4 by the spectral element 812 and is incident into the spatial modulator 820.

Each pixel of the spatial modulator 820 is made to correspond to light of each separated wavelength, and at least one of transmittance, reflectance, or an optical path of each wavelength component is controlled through electrical control of each pixel. With this, the optical switching system 810 that can turn on or off (can select) each wavelength channel with respect to the wavelength multiplexed signal light is configured.

For appropriate wavelength separation in the spectral element 812, light that is incident into the spectral element needs to be parallel light. Accordingly, it is not preferable that light that is emitted from the optical fiber 801 and has a spread is made to be incident into the spectral element 812 as it is.

For this reason, in the optical switching system, the collimating lens is provided upstream of the spectral element that is for wavelength separation of light, and light that is collimated and converted into parallel light is incident into the spectral element.

In an optical switching system of the related art, a ball lens, a semispherical lens, an aspherical lens, or the like is used as the collimating lens. Such lenses have a problem in that a large mounting space is required.

In contrast, the optical switching system 810 of the present invention uses the above-described liquid crystal diffractive lens element 10 as the collimating lens 811. As described above, the liquid crystal diffractive lens element has a thin sheet shape. For this reason, with the optical switching system 810 of the present invention, a mounting space can be reduced and a small-sized optical switching system can be realized.

In addition, optical fibers 802 to 805 are combined as an output-side optical fiber with the above-described optical switching system 810, whereby the optical coupling system 800 having an optical switching function can be constructed.

Here, it is preferable that the liquid crystal diffractive lens element 10, instead of a ball lens, a spherical lens, and an aspherical lens that are known in the related art, is used as the lens element 830.

The liquid crystal diffractive lens element is used, whereby an optical coupling system with a reduced mounting space can be realized. Such an optical coupling system can function as a single device in which a wavelength demultiplexer and an optical switch provided individually in the related art are integrated, whereby it is possible to contribute to a reduction of a mounting size of an optical communication system.

As another preferred aspect, in the above-described optical coupling system 800, the input and the output of light may be reversed. That is, an optical path may be reversed in such a manner that the optical fibers 802 to 805 through which light in a single wavelength mode propagates are provided on an input side, and the optical fiber 801 in a wavelength multiplex mode is provided on an output side. With this, it is possible to construct an optical coupling system that individually switches a plurality of input signals in the single wavelength mode and couples the input signals to output signal light in the wavelength multiplex mode.

In this case, the optical switching system 810 functions as a single device in which an optical multiplexer and an optical switch are integrated, and uses the above-described liquid crystal diffractive lens element as the collimating lens 811, whereby it is possible to contribute to a reduction of a mounting size of an optical communication system. The spectral element 812 can be made to function as an optical combiner that emits light of the wavelengths incident at different angles onto the same optical path. In addition, the collimating lens 811 can be made to function as a condenser lens that collects light incident from the optical combiner (spectral element 812) and couples light with the optical fiber 801.

The liquid crystal diffractive lens element that is used in the optical communication device of the present invention can be assembled into devices other than the devices of the examples shown in the drawings that are mounted in the optical communication device, and a reduction of a mounting space can be achieved like the above-described devices. Accordingly, the present invention should not be interpreted to be limited to the above-described devices.

### EXPLANATION OF REFERENCES

10: liquid crystal diffractive lens element
20: support
24: alignment film
26, 26A: optically anisotropic layer
30: liquid crystal compound
30A: optical axis
52: liquid crystal compound
56: optically anisotropic layer
80: exposure device
82: laser
84: light source
86, 94: polarization beam splitter
90A, 90B: mirror
96: λ/4 plate
92: lens
200: optical transmitter optical assembly
201: laser
202: collimating lens
203: optical isolator
203a: first polarizer
203b: azimuth rotator
203c: second polarizer
204: etalon
205: condenser lens
206: ferrule
300: lens-optical isolator integrated element
400: wavelength demultiplexer
410: socket
411: collimating lens
416: parallel light
420: base
430: reflector
441: demultiplexer block
443: narrowband wavelength selective filter
450: folding prism
460: condenser lens array
460A, 460B, 460C, 460D: condenser lens
700: optical coupling system
702: optical fiber
703: light
704: incidence-side lens element
705: birefringent plate
706: emission-side lens element
710: optical displacer
720: photonic device
721, 722: grating coupler
723, 724: polarized light
800: optical coupling system
801, 802, 803, 804, 805: optical fiber
802a, 803a, 804a, 805a: optical coupler
810: optical switching system
811: collimating lens
812: spectral element
820: spatial modulator
830: lens element
M: laser light
MP: P-polarized light
MS: S-polarized light
L₁, L₄: incident light
L₂, L₅: transmitted light
Q1, Q2: absolute phase
E1, E2: equiphase surface

What is claimed is:

1. An optical communication device comprising:
a liquid crystal diffractive lens element having an optically anisotropic layer formed of a composition containing a liquid crystal compound, as a lens element,
wherein the optically anisotropic layer of the liquid crystal diffractive lens element has a liquid crystal alignment pattern in which an orientation of an optical axis derived from the liquid crystal compound changes while continuously rotating toward one direction, in a radial shape from an inside toward an outside, and
in the liquid crystal alignment pattern, in a case where a length over which the orientation of the optical axis derived from the liquid crystal compound rotates by 180° in the one direction in which the orientation of the optical axis derived from the liquid crystal compound changes while continuously rotating is set as a single period, the length of the single period gradually decreases from the inside toward the outside.

2. The optical communication device according to claim 1, further comprising:
a laser; and
a wavelength locker unit,
wherein the wavelength locker unit has a collimating lens, an optical isolator that regulates a traveling direction of light transmitted through the collimating lens, and an etalon that processes light transmitted through the optical isolator, and the collimating lens is the liquid crystal diffractive lens element, and
the optical communication device acts as a wavelength locker.

3. The optical communication device according to claim 2,
wherein the wavelength locker unit has a condenser lens downstream of the etalon in the traveling direction of the light.

4. The optical communication device according to claim 2,
wherein the collimating lens and the optical isolator are integrated.

5. The optical communication device according to claim 1, further comprising:
a base; and
a socket that is provided for connection of an optical fiber, a collimating lens through which light that is emitted from the optical fiber connected to the socket is transmitted, a demultiplexer block that is provided for wavelength separation of light transmitted through the collimating lens, and a condenser lens array having a plurality of condenser lenses that collect light of each wavelength range subjected to the wavelength separation by the demultiplexer block, the socket, the collimating lens, a demultiplexer block, and the condenser lens array being held on the base,
wherein the condenser lenses of the condenser lens array are the liquid crystal diffractive lens element, and
the optical communication device acts as a wavelength demultiplexer.

6. The optical communication device according to claim 5, further comprising:
a folding prism that is held in the base downstream of the demultiplexer block in a traveling direction of light and folds the light of each wavelength range subjected to the wavelength separation by the demultiplexer block.

7. The optical communication device according to claim 6,
wherein, in a case where a surface on which the demultiplexer block is held is a front surface of the base, the condenser lens array is held on a back surface of the base, and
the light folded by the folding prism is transmitted through the base and is incident on the condenser lens array.

8. The optical communication device according to claim 1,
further comprising:
an optical displacer that is provided for polarization separation,
wherein the optical displacer has an incidence-side lens element, and a birefringent plate that is provided for the polarization separation of light transmitted through the incidence-side lens element, and
the incidence-side lens element is the liquid crystal diffractive lens element.

9. The optical communication device according to claim 8,
wherein the optical displacer has an emission-side lens element that adjusts an optical path of the light subjected to the polarization separation in the birefringent plate, downstream of the birefringent plate in a traveling direction of light.

10. The optical communication device according to claim 8, further comprising:
an optical fiber,
wherein the incidence-side lens element transmits light emitted from the optical fiber.

11. The optical communication device according to claim 8, further comprising:
a photonic device that includes a grating coupler, downstream of the optical displacer in a traveling direction of light,
wherein the optical communication device functions as a polarization multiplex mode optical receiver.

12. The optical communication device according to claim 1, further comprising:
a collimating lens;
a spectral element that is provided for wavelength separation of light transmitted through the collimating lens; and
a spatial modulation element that modulates the light subjected to the wavelength separation by the spectral element,
wherein the collimating lens is the liquid crystal diffractive lens element, and
the optical communication device acts as an optical switching system.

13. The optical communication device according to claim 3,
wherein the collimating lens and the optical isolator are integrated.

14. The optical communication device according to claim 9, further comprising:
an optical fiber,
wherein the incidence-side lens element transmits light emitted from the optical fiber.

15. The optical communication device according to claim 9, further comprising:
a photonic device that includes a grating coupler, downstream of the optical displacer in a traveling direction of light,
wherein the optical communication device functions as a polarization multiplex mode optical receiver.

16. The optical communication device according to claim 10, further comprising:
a photonic device that includes a grating coupler, downstream of the optical displacer in a traveling direction of light,
wherein the optical communication device functions as a polarization multiplex mode optical receiver.
